(19) United States
(12) Patent Application Publication
(10) Pub. No.: US 2024/0380180 A1
(43) Pub. Date: Nov. 14, 2024

(54) SEMICONDUCTOR LASER ELEMENT AND METHOD FOR MANUFACTURING THE SAME

(71) Applicant: Nuvoton Technology Corporation Japan, Kyoto (JP)

(72) Inventors: Koji NAKATSU, Toyama (JP); Yoshihiko OKAWAUCHI, Toyama (JP)

(21) Appl. No.: 18/781,540

(22) Filed: Jul. 23, 2024

Related U.S. Application Data
(63) Continuation of application No. PCT/JP2023/001298, filed on Jan. 18, 2023.

(30) Foreign Application Priority Data
Jan. 31, 2022 (JP) 2022-012749

(51) Int. Cl. H01S 5/22; H01S 5/02; H01S 5/10; H01S 5/24

(52) U.S. Cl. CPC H01S 5/22; H01S 5/0203; H01S 5/1082; H01S 5/24

(57) ABSTRACT

A semiconductor laser element includes a substrate and a semiconductor stacked structure that is provided on one face of the substrate. The semiconductor stacked structure includes an optical waveguide. A pair of first recesses are provided in an other face of the substrate, the pair of first recesses extending in the resonator length direction. Both end portions of each of the pair of first recesses are located in positions recessed from end faces of the semiconductor stacked structure. Second recesses are provided in the semiconductor stacked structure, the second recesses extending from the end faces of the semiconductor stacked structure in the resonator length direction. In a top view, the second recesses are provided on both sides of the optical waveguide, and are each provided between a corresponding one of the pair of first recesses and the optical waveguide.

### CROSS REFERENCE TO RELATED APPLICATIONS

This is a continuation application of PCT International Application No. PCT/JP2023/001298 filed on Jan. 18, 2023, designating the United States of America, which is based on and claims priority of Japanese Patent Application No. 2022-012749 filed on Jan. 31, 2022. The entire disclosures of the above-identified applications, including the specifications, drawings and claims are incorporated herein by reference in their entirety.

### FIELD

The present disclosure relates to a semiconductor laser element and a method for manufacturing the same.

### BACKGROUND

Since semiconductor laser elements have merits such as a long service life, high efficiency, and compactness, they are used as light sources of various products such as projectors, optical disks, vehicle headlamps, and lighting devices or laser processing devices. In recent years, nitride-based semiconductor lasers capable of covering a wavelength range from ultraviolet to blue are increasingly researched and developed as semiconductor laser elements.

It is possible to manufacture semiconductor laser elements by splitting a semiconductor stacked substrate in which a plurality of semiconductor layers are stacked on a wafer, to cut out a plurality of bar-shaped substrates, and by further splitting each of the plurality of bar-shaped substrates into pieces. In such a splitting process, a defect such as splitting away from a planned split line or partial chipping occurs.

In particular, unlike a gallium arsenide-based laser used in optical pickup or optical communications, for a nitride-based semiconductor laser, since splitting is performed, in a splitting process, along crystal faces that are not cleavage faces, a defect such as splitting away from a planned split line or partial chipping is likely to occur.

In view of the above, conventionally, a technique for manufacturing a semiconductor laser element by splitting a wafer using guide recesses has been proposed. For example, Patent Literature (PTL) 1 discloses a method for splitting a wafer in which a plurality of semiconductor layers are stacked, by forming split recesses by irradiating a back face of the wafer with laser light.

### CITATION LIST

### Patent Literature

PTL 1: International Publication Number WO 2008/047751

### SUMMARY

### Technical Problem

However, even if the method disclosed in PTL 1 is used, a semiconductor laser element cracks in a splitting process of splitting a semiconductor stacked substrate in which a plurality of semiconductor layers are stacked on a wafer or a splitting process of splitting each of bar-shaped substrates resulting from splitting the semiconductor r stacked substrate, and the reliability of the semiconductor laser element is reduced.

The present disclosure has been conceived to solve such a problem, and has an object to provide a semiconductor laser element and a method for manufacturing the same that are capable of inhibiting reduction of reliability due to a crack occurring during a manufacturing process.

### Solution to Problem

In order to achieve the above object, a first semiconductor laser element according to one aspect of the present disclosure is a semiconductor laser element including a resonator end face and a pair of lateral faces that intersect the resonator end face, the semiconductor laser element comprising: a substrate; and a semiconductor stacked structure that is provided on one face of the substrate and in which a plurality of semiconductor layers are stacked, wherein the semiconductor stacked structure includes an optical waveguide that extends in a resonator length direction of the semiconductor laser element, a pair of first recesses are provided in an other face of the substrate as indentations in the pair of lateral faces, the pair of first recesses extending in the resonator length direction, both end portions of each of the pair of first recesses in the resonator length direction are located in positions recessed from end faces of the semiconductor stacked structure, a plurality of second recesses are provided in the semiconductor stacked structure, the plurality of second recesses extending from one of the end faces of the semiconductor stacked structure in the resonator length direction, and in a top view, the plurality of second recesses are provided on both sides of the optical waveguide, and are each provided between a corresponding one of the pair of first recesses and the optical waveguide.

Moreover, a second semiconductor laser element according to one aspect of the present disclosure is a semiconductor laser element comprising: a substrate; and a semiconductor stacked structure that is provided on one face of the substrate and in which a plurality of semiconductor layers are stacked. The semiconductor stacked structure includes a ridge portion that extends in a resonator length direction of the semiconductor laser element, and a wing portion on each side of the ridge portion, the wing portion having a same height as the ridge portion. A wingless portion is provided in a vicinity of an end face of the semiconductor stacked structure, the wingless portion being a portion in which the wing portion is not provided, and a projection is provided on the surface of the end edge of the semiconductor stacked structure in the direction orthogonal to the resonator length direction, in the wingless portion.

Furthermore, a method for manufacturing a semiconductor laser element according to one aspect of the present disclosure comprising: a process of stacking a plurality of semiconductor layers on one face of a substrate to prepare a semiconductor stacked substrate including a semiconductor stacked structure; a first etching process of etching the semiconductor stacked structure; a second etching process of etching the semiconductor stacked structure after the first etching process; a first splitting process of splitting the semiconductor stacked substrate into a plurality of bar-shaped substrates each of which includes a plurality of optical waveguides; a process of forming a plurality of first recesses on a back face of the semiconductor stacked substrate or a back face of each of the plurality of bar-shaped substrates; and a second splitting process of splitting each of the plurality of bar-shaped substrates along the plurality of first recesses to prepare a plurality of semiconductor laser elements each of which includes one optical waveguide, wherein in the first etching process, a recessed portion is formed in the semiconductor stacked structure, in the second etching process, the recessed portion is further etched to form a plurality of second recesses, and a ridge portion is formed as the one optical waveguide in the semiconductor stacked structure, and in a top view, the plurality of second recesses are formed to extend, on both sides of the one optical waveguide, from an end face of the semiconductor stacked structure in a resonator length direction of the plurality of semiconductor laser elements, and are each formed between a corresponding one of the plurality of first recesses and the one optical waveguide.

### Advantageous Effects

According to the present disclosure, it is possible to obtain a semiconductor laser element that is capable of inhibiting reduction of reliability due to a crack occurring during a manufacturing process.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a top view of a semiconductor laser element according to an embodiment.

FIG. 2A is a cross-sectional view of the semiconductor laser element according to the embodiment taken along line IIA-IIA in FIG. 1.

FIG. 2B is a cross-sectional view of the semiconductor laser element according to the embodiment taken along line IIB-IIB in FIG. 1.

FIG. 2C is a cross-sectional view of the semiconductor laser element according to the embodiment taken along line IIC-IIC in FIG. 1.

FIG. 3 is a side view of the semiconductor laser element according to the embodiment.

FIG. 4A is a diagram for illustrating a process of forming a semiconductor stacked structure in a method for manufacturing a semiconductor laser element according to the embodiment.

FIG. 4B is a diagram for illustrating a process of forming a first resist in the method for manufacturing the semiconductor laser element according to the embodiment.

FIG. 4C is a diagram for illustrating a first etching process in the method for manufacturing the semiconductor laser element according to the embodiment.

FIG. 4D is a diagram for illustrating a process of removing the first resist in the method for manufacturing the semiconductor laser element according to the embodiment.

FIG. 4E is a diagram for illustrating a process of forming a second resist in the method for manufacturing the semiconductor laser element according to the embodiment.

FIG. 4F is a diagram for illustrating a second etching process in the method for manufacturing the semiconductor laser element according to the embodiment.

FIG. 4G is a diagram for illustrating a process of forming an insulating film in the method for manufacturing the semiconductor laser element according to the embodiment.

FIG. 4H is a diagram for illustrating a process of removing the insulating film in the method for manufacturing the semiconductor laser element according to the embodiment.

FIG. 4I is a diagram for illustrating a process of forming a p-side electrode in the method for manufacturing the semiconductor laser element according to the embodiment.

FIG. 4J is a diagram for illustrating a process of forming an n-side electrode in the method for manufacturing the semiconductor laser element according to the embodiment.

FIG. 5 is a cross-sectional SEM image of a portion corresponding to region V enclosed by a dashed line in (d) of FIG. 4H.

FIG. 6 is a diagram illustrating a configuration of a semiconductor laser element manufactured by the method for manufacturing the semiconductor laser element according to the embodiment.

FIG. 7 is a cross-sectional view of a semiconductor laser element according to a variation.

FIG. 8 is a diagram for illustrating a process of splitting a bar-shaped substrate into a plurality of semiconductor laser elements (a process of splitting into pieces).

FIG. 9 is a diagram illustrating a configuration of a semiconductor laser element of a comparative example.

### DESCRIPTION OF EMBODIMENT

### Circumstances Leading to One Aspect of the Present Disclosure

First, before an embodiment of the present disclosure is described, circumstances leading to one aspect of the present disclosure are described.

Generally, when semiconductor laser elements are manufactured in quantity, a semiconductor stacked substrate in which a plurality of semiconductor layers are stacked on a substrate that is a wafer is split to form a plurality of bar-shaped substrates (a primary splitting process), and after coating films are provided on both end faces of the plurality of bar-shaped substrates, each of the plurality of bar-shaped substrates is separated into a plurality of semiconductor laser elements by splitting the bar-shaped substrate into pieces (a secondary splitting process). In this manner, it is possible to obtain, from one wafer, a plurality of semiconductor laser elements that are to be laser chips.

Conventionally, a method for forming in advance split recesses (guide recesses) in a semiconductor stacked substrate or a bar-shaped substrate and then splitting the bar-shaped substrate along the recesses when the bar-shaped substrate is split into pieces has been proposed. In this case, it is conceivable that the split recesses are formed by using the method disclosed in PTL 1. Specifically, it is conceivable that the split recesses are formed by irradiating a back face of the semiconductor stacked substrate or the bar-shaped substrate with laser light. At this time, in order to keep resonator end faces of semiconductor laser elements from being thermally damaged by laser light when recesses are formed, laser light is emitted to cause end portions of the recesses in a resonator length direction to be located in positions recessed from the resonator end faces. In other words, the laser light is emitted to cause the split recesses not to reach resonator end faces on a front side and a rear side of the bar-shaped substrate.

However, when actually manufacturing semiconductor laser elements by using such a method, the inventors of the present application has found that a semiconductor laser element cracks in a process of splitting a bar-shaped substrate into pieces. The following describes this point in detail.

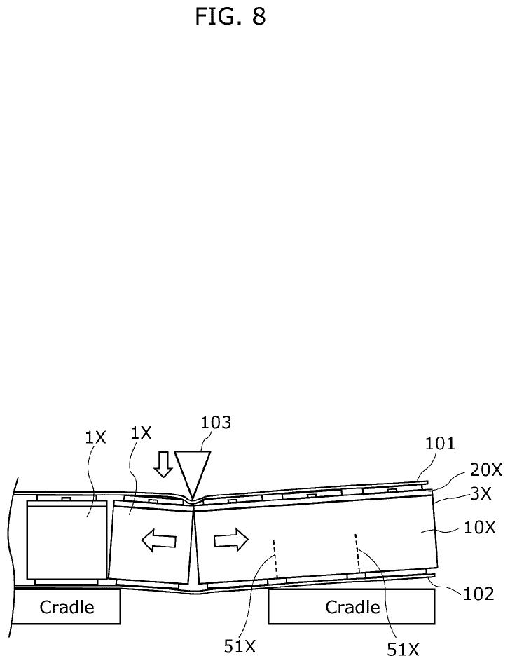

As shown in FIG. 8, blade-shaped jig 103 such as a cutter is sequentially pushed from above bar-shaped substrate 3X at positions corresponding to split recesses 51X in a state in which bar-shaped substrate 3X in which split recesses 51X are formed in a back face of substrate 10X is interposed between adhesive sheet 101 and protection film 102. Accordingly, it is possible to split bar-shaped substrate 3X into a plurality of semiconductor laser elements 1X.

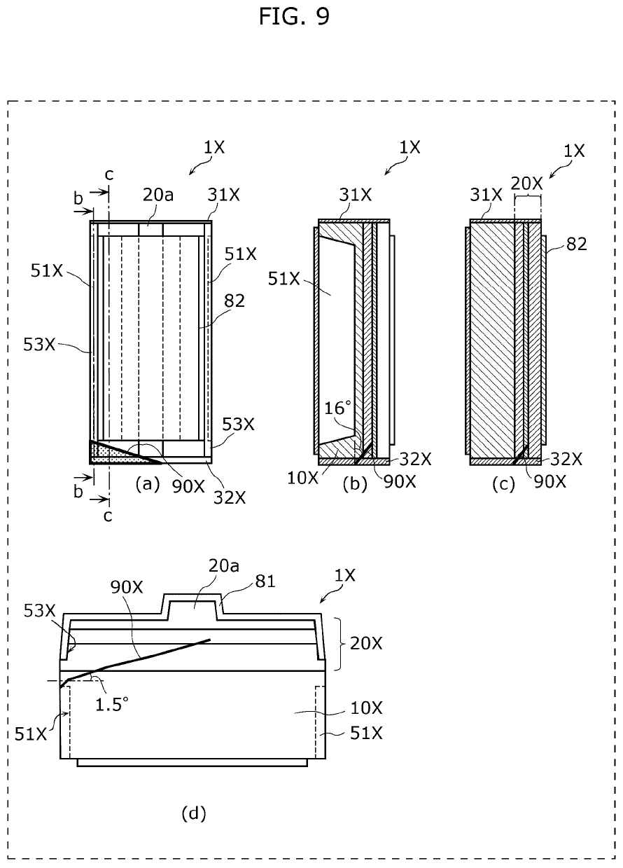

At this time, by observing semiconductor laser element 1X obtained, it was found that, as shown in FIG. 9, crack 90X occurs at a corner portion defined by a resonator end face and a lateral face of semiconductor laser element 1X, crack 90X extending obliquely upward from the vicinity of an interface between substrate 10X and semiconductor stacked structure 20X to a portion below ridge portion 20a. Crack 90X extending to the portion below ridge portion 20a as above reduces the reliability of semiconductor laser element 1X.

It should be noted that FIG. 9 is a diagram illustrating a configuration of semiconductor laser element 1X of a comparative example when semiconductor laser element 1X is manufactured by the method disclosed in PTL 1. In FIG. 9, (a) is a top view of semiconductor laser element 1X, (b) is a cross-sectional view taken along line b-b shown in (a), and (c) is a cross-sectional view taken along line c-c shown in (a). (d) of FIG. 9 is a side view when semiconductor laser element 1X is viewed from a rear end face side with omission of coating film 32X of an end face. In addition, the thick line in FIG. 9 indicates crack 90X that has occurred in semiconductor laser element 1X, and the dot-hatched region indicates a region in which crack 90X has occurred.

By observing the plurality of semiconductor laser elements 1X obtained, it was found that cracks 90X occur extensively in a trigonal planar manner as shown in (a) of FIG. 9. Specifically, as shown in (b) and (d) of FIG. 9, it was found that in a cross section orthogonal to a resonator length direction of semiconductor laser element 1X, after first advancing obliquely upward from a lateral face of semiconductor stacked structure 20X in the vicinity of recess 51X, many cracks 90X that have occurred extend slightly obliquely upward at an angle of approximately 1.5° relative to a principal face of substrate 10X in a location away from recess 51X, and in a cross section parallel to the lateral face of semiconductor laser element 1X, cracks 90X extend obliquely upward from an end face of semiconductor stacked structure 20X at an angle of approximately 16° relative to the principal face of substrate 10X. Moreover, it was also found that many cracks 90X occur from a portion lower than a portion of the surface of semiconductor stacked structure 20X located closest to a substrate 10X side (a top face of split recess 53X in (d) of FIG. 9) by approximately 2 μm. Furthermore, it was also found that many cracks 90X occur especially on a rear end face side of semiconductor laser element 1X.

It should be noted that in each of two right and left semiconductor laser elements 1X split by blade-shaped jib 103 (see FIG. 8), although many cracks 90X occur from the left lateral face of semiconductor laser element 1X, cracks 90X sometimes occur from the right lateral face of semiconductor laser element 1X. In addition, although crack 90X does not extend to a position overlapping recess 51X in a top view, crack 90X sometimes extends to the position overlapping recess 51X.

After investigating causes of cracks 90X occurring in the above manner, the inventors of the present application have deduced the causes from forming split recesses 51X for splitting into pieces in a back face of substrate 10X and a low likelihood of cracks occurring in the vicinity of front-side and rear-side resonator end faces due to split recesses 51X being formed not to reach the front-side and rear-side resonator end faces.

Moreover, since coating film 32X provided on the rear-side resonator end face has a thickness greater (e.g., approximately eight times greater) than a thickness of coating film 31X provided on the front-side resonator end face in order for laser light to be emitted in a front direction, a crack is less likely to occur in the vicinity of the rear-side resonator end face than the front-side resonator end face. For this reason, it was considered that many cracks 90X occur in the rear-side resonator end face.

In response, after diligently studying such a problem, the inventors of the present application have arrived at an idea of providing a structure that prevents crack 90X from advancing to a portion below ridge portion 20a even if crack 90X occurs at the time of splitting into pieces. Specifically, the inventors have arrived at an idea of forming, in semiconductor stacked structure 20X, recesses for preventing crack 90X from advancing.

As stated above, the present disclosure has been conceived in response to the occurrence of cracks, and has a first object to provide a semiconductor laser element capable of preventing a crack from advancing to a portion below a ridge portion even if the crack occurs at the time of splitting into pieces.

Furthermore, although a protection component comprising SiO₂ etc. may be disposed on a wafer in a splitting process of splitting the wafer (a primary splitting process, a secondary splitting process), in this case, a chip (an end face step etc.) may occur in ridge portion 20a of a semiconductor laser element due to stress at the time of splitting being applied to ridge portion 20a.

The present disclosure has been conceived in response to such a problem, and has a second object to provide a semiconductor laser element capable of preventing a crack from occurring in a portion that becomes a ridge portion in the splitting process.

Hereinafter, an embodiment of the present disclosure is described with reference to the drawings. It should be noted that the embodiment described below shows a specific example of the present disclosure. The numerical values, shapes, materials, constituent elements, the arrangement and connection of the constituent elements, and steps (processes), and order of the steps, etc. indicated in the following embodiment are mere examples, and are not intended to limit the present disclosure. Thus, among the constituent elements in the following embodiment, those not recited in any one of the independent claims that indicate the broadest concepts of the present disclosure are described as optional constituent elements.

Moreover, the respective figures are schematic diagrams and are not necessarily precise illustrations. Accordingly, the figures are not necessarily to scale etc. The same reference signs are assigned to substantially identical elements in the figures, and overlapping descriptions thereof are omitted or simplified.

Furthermore, in this Specification, the terms “above” and “below” do not refer to the upward (vertically upward) direction and downward (vertically downward) direction in terms of absolute spatial recognition, and are used as terms defined by relative positional relationships based on the stacking order of a stacked configuration. In addition, the terms “above” and “below” are applied not only when two constituent elements are arranged at intervals without another constituent element located between the two constituent elements, but also when two constituent elements are arranged adjacent to each other.

### Embodiment

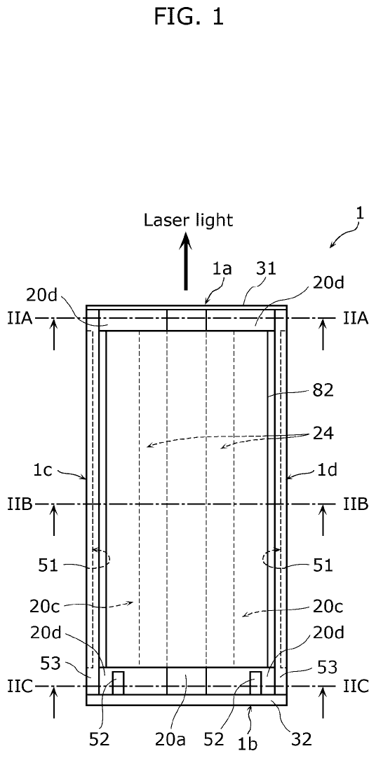

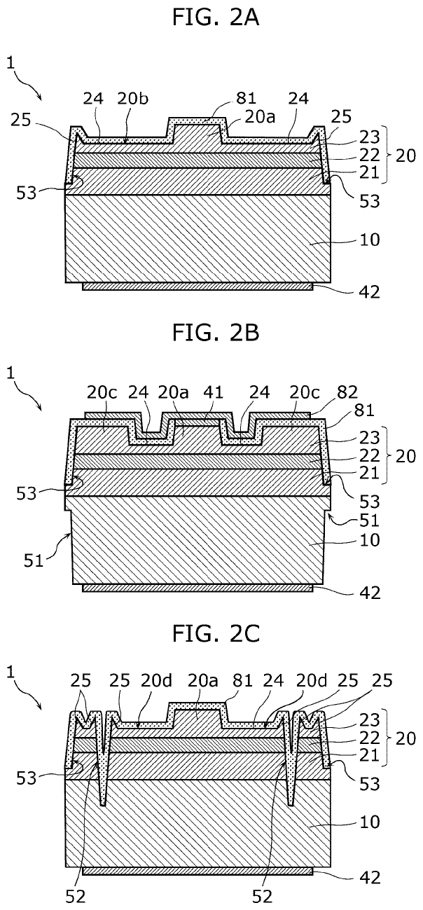

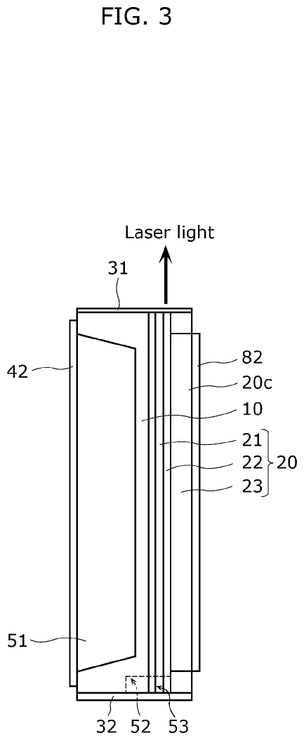

First, a configuration of semiconductor laser element 1 according to an embodiment is described with reference to FIG. 1 to FIG. 3. FIG. 1 is a top view of semiconductor laser element 1 according to the embodiment. FIG. 2A to FIG. 2C are each a cross-sectional view of semiconductor laser element 1 according to the embodiment. FIG. 2A is a cross-sectional view taken along line IIA-IIA in FIG. 1, FIG. 2B is a cross-sectional view taken along line IIB-IIB in FIG. 1, and FIG. 2C is a cross-sectional view taken along line IIC-IIC in FIG. 1. FIG. 3 is a side view of semiconductor laser element 1 according to the embodiment. It should be noted that insulating film 81 is omitted in FIG. 1.

As shown in FIG. 1, semiconductor laser element 1 includes front end face 1a and rear end face 1b each of which is a resonator end face, and first lateral face 1c and second lateral face 1d each of which is a face that intersects the resonator end faces.

Front end face 1a is an end face on a front side of semiconductor laser element 1, and is a resonator end face through which laser light is emitted. Rear end face 1b is an end face on a rear side of semiconductor laser element 1, and is a resonator end face through which no laser light is emitted. Front end face 1a and rear end face 1b face each other as a pair of resonator end faces. Rear end face 1b is an end face on the opposite side of front end face 1a.

First lateral face 1c is a face on one lateral side of semiconductor laser element 1. Second lateral face 1d is a face on an other lateral side of semiconductor laser element 1. First lateral face 1c and second lateral face 1d face each other as a pair of lateral faces. First lateral face 1c and second lateral face 1d are each a face orthogonal to front end face 1a and rear end face 1b.

As shown in FIG. 1 to FIG. 3, semiconductor laser element 1 includes substrate 10 and semiconductor stacked structure 20 provided on a top face that is one face of substrate 10. Semiconductor stacked structure 20 is a structure obtained by stacking a plurality of semiconductor layers, and includes a PN junction portion.

Semiconductor laser element 1 in the present embodiment is a nitride semiconductor laser that comprises a nitride-based semiconductor material. Accordingly, semiconductor stacked structure 20 is a nitride semiconductor stacked body that is obtained by stacking a plurality of nitride semiconductor layers each of which comprises a nitride-based semiconductor material. Specifically, semiconductor laser element 1 is a GaN-based nitride semiconductor laser. Laser light emitted from semiconductor laser element 1 is, for example, light in a wavelength band from ultraviolet to blue.

Semiconductor laser element 1 includes an optical waveguide that uses front end face 1a and rear end face 1b as resonator reflective mirrors. Specifically, semiconductor stacked structure 20 includes the optical waveguide. The optical waveguide extends in a resonator length direction of semiconductor laser element 1. In the present embodiment, ridge portion 20a is provided as the optical waveguide to semiconductor stacked structure 20. Accordingly, ridge portion 20a is provided to extend in the resonator length direction of semiconductor laser element 1. Ridge portion 20a is in a protruding shape and provided by carving out semiconductor stacked structure 20. It should be noted that semiconductor laser element 1 is in an elongated shape in the resonator length direction. The length of semiconductor laser element 1 in the resonator length direction is, as an example, at least 800 μm, and is 1200 μm in the present embodiment.

In semiconductor laser element 1, front end face 1a and rear end face 1b constitute a laser resonator. For this reasons, rear end face 1b has a reflectivity higher than a reflectivity of front end face 1a. As an example, front end face 1a has a reflectivity of 5%, and rear end face 1b has a reflectivity of 95%.

Specifically, as shown in FIG. 1, first coating film 31 is provided as a reflective film on the front side of semiconductor laser element 1, and second coating film 32 is provided as a reflective film on the rear side of semiconductor laser element 1. First coating film 31 is provided on front end face 1a of semiconductor stacked structure 20, and second coating film 32 is provided on rear end face 1b of semiconductor stacked structure 20. First coasting film 31 and second coating film 32 each include a dielectric multilayer film in which a plurality of dielectric films are stacked. In the present embodiment, second coating film 32 on the rear side has a thickness greater than a thickness of first coating film 31 on the front side. Second coating film 32 has, as an example, a thickness at least twice as great as a thickness of first coating film 31, and has a thickness approximately eight times as great as the thickness of first coating film 31 in the present embodiment.

Substrate 10 is a semiconductor substrate comprising GaN or SiC etc., or an insulating substrate such as a sapphire substrate. Substrate 10 is, for example, an n-type GaN substrate comprising hexagonal GaN single crystals. In the present embodiment, an n-type GaN substrate whose principal plane is the (0001) plane is used as substrate 10.

As shown in FIG. 2A to FIG. 2C, semiconductor stacked structure 20 includes, on substrate 10, first semiconductor layer 21 on an n-side, active layer 22, and second semiconductor layer 23 on a p-side in stated order. Active layer 22 is the PN junction portion in semiconductor stacked structure 20. It is possible to provide first semiconductor layer 21, active layer 22, and second semiconductor layer 23 by epitaxially growing a nitride-based semiconductor material using metalorganic chemical vapor deposition (MOCVD). For example, each of first semiconductor layer 21, active layer 22, and second semiconductor layer 23 is configured as below.

First semiconductor layer 21 includes at least an n-type cladding layer. In the present embodiment, first semiconductor layer 21 includes an n-side cladding layer that includes the n-type cladding layer, and an n-side light guide layer provided on the n-side cladding layer. The n-side cladding layer and the n-side light guide layer may each be a single layer or a multiple layer.

As an example, the n-side cladding layer is an n-side cladding layer (n-AGaN layer) that is doped with silicon and comprises AlGaN. The n-side light guide layer is a light guide layer (un-GaN layer) that is undoped and comprises GaN.

Active layer 22 is a quantum well active layer. Active layer 22 has a stacked structure in which well layers that are undoped and comprise InGaN and barrier layers that are undoped and comprise InGaN are alternately stacked. Active layer 22 may have one of a single quantum well (SQW) structure or a multi-quantum well (MQW) structure. In the present embodiment, active layer 22 has a five-layer structure that includes a barrier layer that comprises InGaN, a well layer that comprises InGaN, a barrier layer that comprises InGaN, a well layer that comprises InGaN, and a barrier layer that comprises InGaN.

Second semiconductor layer 23 includes at least a p-type cladding layer. In the present embodiment, second semiconductor layer 23 includes: a p-side light guide layer; an overflow suppression (OFS) layer provided on the p-side light guide layer; a p-side cladding layer that is provided on the OFS layer and includes a p-type cladding layer; and a contact layer that is provided on the p-side cladding layer. The p-side light guide layer, the OFS layer, the p-side cladding layer, and the contact layer may each be a single layer or a multiple layer.

As an example, the p-side light guide layer is a p-side light guide layer (un-GaN layer) that is undoped and comprises GaN.

The OFS layer is a p-type OFS layer (p-AlGaN layer) that is doped with magnesium as impurities and comprises AlGaN.

The p-side cladding layer is a p-type p-side cladding layer (p-AlGaN layer) that is doped with magnesium as impurities.

The contact layer is a p-type contact layer (p-GaN layer) that is doped with magnesium as impurities and comprises GaN.

As shown in FIG. 1 to FIG. 2C, recessed portions 24 are provided to semiconductor stacked structure 20 configured as above. By providing recessed portions 24, ridge portion 20a and flat portions 20b that extend laterally from the roots of ridge portion 20a are provided to semiconductor stacked structure 20. Recessed portions 24 are provided by carving out semiconductor stacked structure 20 by etching. As shown in FIG. 2A to FIG. 2C, recessed portions 24 are carved into second semiconductor layer 23 in the present embodiment. In other words, ridge portion 20a and flat portions 20b are provided in second semiconductor layer 23. Specifically, ridge portion 20a is provided in the p-side cladding layer and the contact layer. As an example, ridge portion 20a includes: a protruding portion that is provided in the p-side cladding layer; and a contact layer that is provided on the protruding portion. The uppermost layer of ridge portion 20a is the contact layer. Additionally, flat portions 20b are provided in the p-side cladding layer. A flat face of flat portion 20b is the bottom of recessed portion 24, and is the surface of the p-side cladding layer in recessed portion 24.

The width and height of ridge portion 20a are not particularly limited. As an example, the ridge width (stripe width) of ridge portion 20a is at least 1 μm and at most 100 μm, and the height of ridge portion 20a is at least 100 nm and at most 1000 nm. It should be noted that although the width of the contact layer is the same as the ridge width of ridge portion 20a, the present disclosure is not limited to this example.

Moreover, in the present embodiment, by providing recessed portions 24 to semiconductor stacked structure 20, wing portions 20c in a protruding shape are provided to semiconductor stacked structure 20 as shown in FIG. 1 and FIG. 2B. In other words, semiconductor stacked structure 20 includes ridge portion 20a and wing portions 20c as a convex structure. As stated above, in the present embodiment, recessed portions 24 are provided by carving out second semiconductor layer 23. Accordingly, wing portions 20c each comprise second semiconductor layer 23 and have the same height as ridge portion 20a. Specifically, as with ridge portion 20a, wing portions 20c each include the p-side cladding layer and the contact layer. It should be noted that the top faces of ridge portion 20a and wing portions 20c are flat faces.

As shown in FIG. 1 and FIG. 2B, wing portions 20c are provided on the both sides of ridge portion 20a. In other words, semiconductor stacked structure 20 includes a pair of wing portions 20c. Ridge portion 20a is sandwiched between the pair of wing portions 20c via recessed portions 24. As with ridge portion 20a, the pair of wing portions 20c extend in the resonator length direction of semiconductor laser element 1. By providing wing portions 20c on the both sides of ridge portion 20a as above, it is possible to reduce stress applied to ridge portion 20a when semiconductor laser element 1 is junction-down mounted.

Although the width of each of the pair of wing portions 20c is greater than the width of ridge portion 20a in the present embodiment, the present disclosure is not limited to this example. Additionally, although the pair of wing portions 20c have the same width, the pair of wing portions 20c may have different widths.

Furthermore, as shown in FIG. 1, wingless portion 20d that is a portion in which wing portion 20c is not provided is provided in the vicinity of an end face of semiconductor stacked structure 20. In other words, wingless portion 20d is part of recessed portion 24. In the present embodiment, wingless portion 20d is provided in the vicinity of each of the front end face and the rear end face of semiconductor stacked structure 20.

As shown in FIG. 2C, projection 25 is provided on the surface of an end edge of semiconductor stacked structure 20 in a direction orthogonal to the resonator length direction of semiconductor stacked structure 20, in wingless portion 20d. Specifically, projection 25 is provided at a border between the surface of semiconductor stacked structure 20 and a lateral face of second recess 52 to be described later. In this case, the end edge of semiconductor stacked structure 20 at which projection 25 is provided becomes the border between the surface of semiconductor stacked structure 20 and the lateral face of second recess 52. In addition, projection 25 is also provided at a border between the surface of semiconductor stacked structure 20 and a lateral face of third recess 53 to be described later. In this case, the end edge of semiconductor stacked structure 20 at which projection 25 is provided becomes the border between the surface of semiconductor stacked structure 20 and the lateral face of third recess 53. In the present embodiment, projection 25 is provided in a horn shape whose cross section is triangular.

As shown in FIG. 2B, p-side electrode 41 is provided on ridge portion 20a of second semiconductor layer 23. Specifically, p-side electrode 41 is provided on the contact layer. In the present embodiment, p-side electrode 41 is provided only on a top face of ridge portion 20a. Although p-side electrode 41 has a width less than the width of ridge portion 20a, p-side electrode 41 may have the same width as ridge portion 20a.

p-side electrode 41 is formed using, for example, at least one of metal materials such as Pt, Ti, Cr, Ni, Mo, and Au. p-side electrode 41 may be a single layer or a multiple layer. In the present embodiment, p-side electrode 41 is a two-layer electrode that includes a Pd layer that comprises Pd and has a thickness of 40 nm, and a Pt layer that comprises Pt and has a thickness of 35 nm. It should be noted that a pad electrode may be provided on p-side electrode 41.

In contrast, n-side electrode 42 is provided on a bottom face (back face) that is an other face of substrate 10. n-side electrode 42 is an ohmic electrode that is in ohmic contact with substrate 10 that is a semiconductor substrate. n-side electrode 42 is formed using, for example, at least one of metal materials such as Cr, Ti, Ni, Pd, Pt, Au, and Ge. In addition, n-side electrode 42 may be a single layer or a multiple layer.

As shown in FIG. 2A to FIG. 2C, semiconductor stacked structure 20 excluding p-side electrode 41 on ridge portion 20a is covered with insulating film 81 that includes a dielectric film that comprises SiO₂ or SiN etc. Specifically, insulating film 81 is provided to cover second semiconductor layer 23 excluding the top face of ridge portion 20a. In other words, insulating film 81 is provided with an opening formed above ridge portion 20a of the contact layer.

Insulating film 81 serves as a current blocking film. Accordingly, the opening of insulating film 81 becomes a current injection window through which current passes. It should be noted that insulating film 81 may be provided up to a lateral face of semiconductor stacked structure 20.

Moreover, as shown in FIG. 2B, pad electrode 82 is provided on p-side electrode 41. Pad electrode 82 is in contact with p-side electrode 41. In the present embodiment, pad electrode 82 is wider than ridge portion 20a, and is also provided on wing portions 20c. In other words, pad electrode 82 is provided on insulating film 81 to cover ridge portion 20a, flat portions 20b (recessed portions 24), and wing portions 20c. Pad electrode 82 comprises a metal material such as Au. Additionally, pad electrode 82 may be provided via an adhesive auxiliary layer that comprises Ti etc. In this case, the adhesion auxiliary layer may be part of pad electrode 82.

A plurality of recesses are formed in semiconductor laser element 1 configured as above. Specifically, as shown in FIG. 1 to FIG. 3, first recesses 51, second recesses 52, and third recesses 53 are formed as the plurality of recesses in semiconductor laser element 1.

First recesses 51 are formed on a back side of semiconductor laser element 1. Specifically, first recesses 51 are formed in a back face of substrate 10. In contrast, second recesses 52 and third recesses 53 are formed on a front side of semiconductor laser element 1. Specifically, second recesses 52 and third recesses 53 are formed in semiconductor stacked structure 20.

First recesses 51 formed in the back face of substrate 10 are guide recesses when a wafer on which a plurality of semiconductor layers are stacked is split. Specifically, as described later, first recesses 51 are guide recesses when each of a plurality of bar-shaped substrates resulting from splitting a semiconductor stacked substrate in which the plurality of semiconductor layers are stacked on the wafer is split into pieces. First recesses 51 are scribe recesses, and it is possible to form first recesses 51 by, for example, irradiating the back face of substrate 10 with laser light. Since it is possible to reduce stress applied to semiconductor laser element 1 at the time of splitting into pieces, by forming first recesses 51 not on the top face but on the bottom face (back face) of substrate 10, it is possible to prevent a crack from occurring.

As shown in FIG. 1 and FIG. 3, first recesses 51 are formed to extend in the resonator length direction of semiconductor laser element 1. In addition, first recesses 51 are each formed in a corresponding one of the pair of lateral faces of semiconductor laser element 1. In other words, a pair of first recesses 51 are formed in semiconductor laser element 1. As shown in FIG. 2B, each of the pair of first recesses 51 is formed as an indentation in the corresponding one of the lateral faces of semiconductor laser element 1 from the back face of substrate 10. The pair of first recesses 51 are formed in the lateral faces of substrate 10. Specifically, one of the pair of first recesses 51 extends in the resonator length direction as an indentation in one of the lateral faces of substrate 10 that corresponds to first lateral face 1c. In addition, an other of the pair of first recesses 51 extends in the resonator length direction as an indentation in an other of the lateral faces of substrate 10 that corresponds to second lateral face 1d.

As shown in FIG. 1 and FIG. 3, both end portions of each of the pair of first recesses 51 in the resonator length direction are located in positions recessed from end faces of semiconductor stacked structure 20. In other words, the both end portions of each first recess 51 in the resonator length direction are each provided not to reach a corresponding one of the end faces of semiconductor stacked structure 20. Specifically, in the vicinity of a front end side of semiconductor stacked structure 20, a portion in which semiconductor stacked structure 20 is kept without providing first recess 51 (a leftover margin) is located between a rear-side end portion of first recess 51 in the resonator length direction and the rear end face of semiconductor stacked structure 20. Similarly, in the vicinity of a rear end side of semiconductor stacked structure 20, a portion in which semiconductor stacked structure 20 is kept without providing first recess 51 (a leftover margin) is located between a front-side end portion of first recess 51 in the resonator length direction and the front end face of semiconductor stacked substrate 20.

In the present embodiment, the bottoms of first recesses 51 are located inside substrate 10. In other words, first recesses 51 are formed not to reach semiconductor stacked structure 20 on a top face side of substrate 10 from the bottom face (back face) of substrate 10. As an example, substrate 10 has a thickness of 83 μm, first recesses 51 have a depth of 55 μm, and the leftover margins have a length of 13 μm.

Second recesses 52 formed in semiconductor stacked structure 20 are each a crack blocking recess for preventing a crack that occurs when a bar-shaped substrate is split into pieces from advancing. It is possible to form second recesses 52 by etching semiconductor stacked structure 20.

As shown in FIG. 1, second recesses 52 are formed from an end face of semiconductor stacked structure 20 in the resonator length direction of semiconductor laser element 1. In the present embodiment, second recesses 52 are formed from the rear end face toward the front end face of semiconductor stacked structure 20. Additionally, second recesses 52 are formed only in the vicinity of the rear end face of semiconductor stacked structure 20. Specifically, although second recesses 52 are formed in wingless portions 20d of semiconductor stacked structure 20, second recesses 52 may be formed across wing portions 20c. It should be noted that second recesses 52 may be also formed in the vicinity of the front end face of semiconductor stacked structure 20. Moreover, as shown in FIG. 1, in a top view, second recesses 52 are formed on the both sides of ridge portion 20a that is the optical waveguide. In other words, a pair of second recesses 52 are formed in semiconductor laser element 1. Each of the pair of second recesses 52 is formed between first recess 51 and ridge portion 20a. Specifically, one of the pair of second recesses 52 is formed between one of the pair of first recesses 51 and ridge portion 20a in a direction orthogonal to the resonator length direction of semiconductor laser element 1. In addition, an other of the pair of second recesses 52 is formed between an other of the pair of first recesses 51 and ridge portion 20a in the direction orthogonal to the resonator length direction of semiconductor laser element 1.

The length of second recess 52 in the resonator length direction may be at least half a distance (a leftover margin) between first recess 51 and the rear end face of semiconductor stacked structure 20. In the present embodiment, the length of second recess 52 in the resonator length direction is at least 10 μm from the rear end face of semiconductor stacked structure 20 and is at most 25 times a distance between third recess 53 and second recess 52. As an example, the length of second recess 52 in the resonator length direction is 14 μm, whereas the length of semiconductor laser element 1 in the resonator length direction is 1200 μm. It should be noted that although the pair of second recesses 52 have the same length in the resonator length direction, the pair of second recesses 52 may have different lengths.

Furthermore, the width of second recess 52 is, as an example, at most 10 μm. In the present embodiment, the width of each second recess 52 is 8 μm. However, if the width is etchable, the width may be further reduced. It should be noted that although the pair of second recesses 52 have the same width, the pair of second recesses 52 may have different widths.

Second recess 52 is deeper than a portion of the surface of semiconductor stacked structure 20 located closest to a substrate 10 side. In the present embodiment, the portion of the surface of semiconductor stacked structure 20 located closest to the substrate 10 side is the bottom of third recess 53. In other words, as shown in FIG. 2C, each second recess 52 is deeper than third recess 53. As an example, the bottom of second recess 52 is located at a position lower than the portion of the surface of semiconductor stacked structure 20 located closest to the substrate 10 side by approximately 2 μm. It should be noted that second recess 52 may be made as deep as third recess 53. In addition, although the pair of second recesses 52 have the same depth, the pair of second recesses 52 may have different depths.

Moreover, lateral faces (inner faces) of second recess 52 are sloped. Specifically, each of a pair of lateral faces that face each other is sloped in second recess 52. In the present embodiment, second recess 52 is formed in a tapered shape to cause the width of second recess 52 to narrow gradually in a depth direction.

Third recesses 53 formed in semiconductor stacked structure 20 are isolation trenches (element isolation trenches) for isolating, for each optical waveguide, a plurality of stacked semiconductor layers, in a semiconductor stacked substrate in which a plurality of semiconductor layers are stacked on a wafer by epitaxial growth.

Accordingly, as shown in FIG. 2A to FIG. 2C, third recesses 53 are each formed in a corresponding one of the pair of lateral faces of semiconductor laser element 1. In other words, a pair of third recesses 53 are formed in semiconductor laser element 1. It is possible to form third recesses 53 by etching the plurality of stacked semiconductor layers.

Each of the pair of third recesses 53 is formed as an indentation in a corresponding one of the lateral faces of semiconductor stacked structure 20 from a top face of semiconductor stacked structure 20. Additionally, as shown in FIG. 1, third recesses 53 are formed to extend in the resonator length direction of semiconductor laser element 1. Specifically, one of the pair of third recesses 53 extends in the resonator length direction as an indentation in one of the lateral faces of semiconductor stacked structure 20. In addition, an other of the pair of third recesses 53 extends in the resonator length direction as an indentation in an other of the lateral faces of semiconductor stacked structure 20. In the present embodiment, the pair of third recesses 53 are formed from the front end face to the rear end face of semiconductor stacked structure 20.

It is possible to form third recesses 53 by carving from the top face of semiconductor stacked structure 20 in a stacking direction. As shown in FIG. 2A to FIG. 2C, third recess 53 is deeper than active layer 22 that is the PN junction portion in semiconductor stacked structure 20. Additionally, in the present embodiment, a lateral face of third recess 53 is sloped. Specifically, the lateral face of third recess 53 is sloped in a manner that the lateral face flares out in the depth direction.

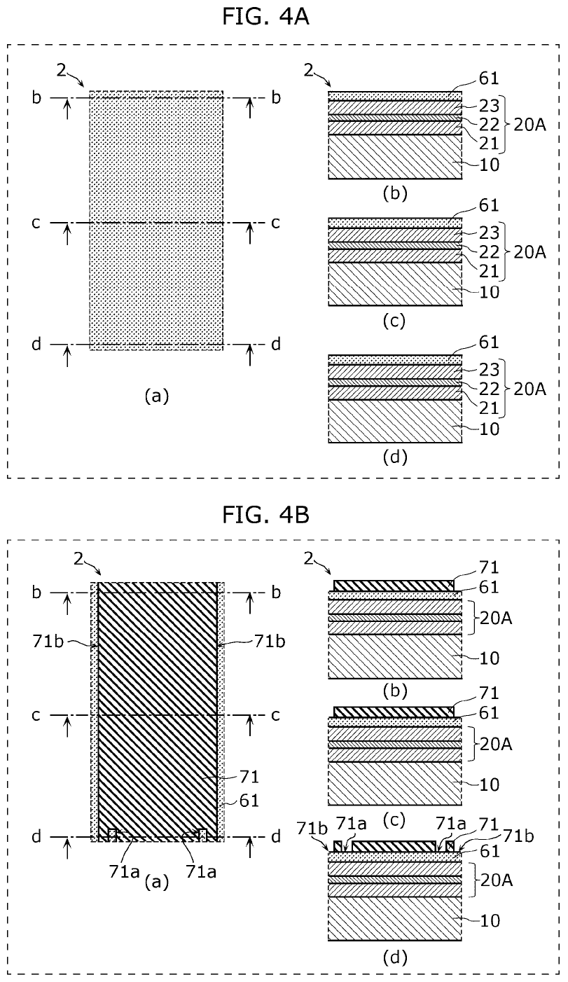

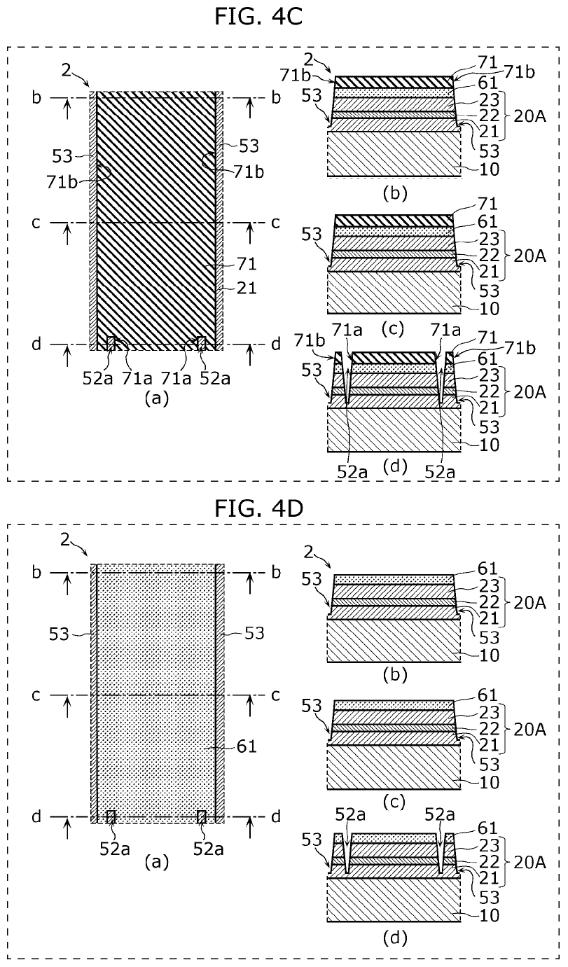

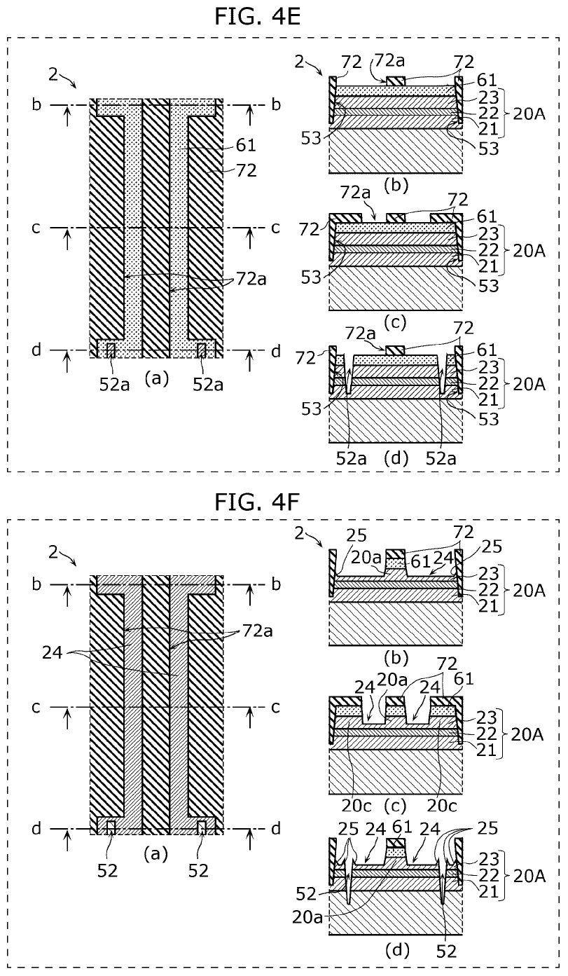

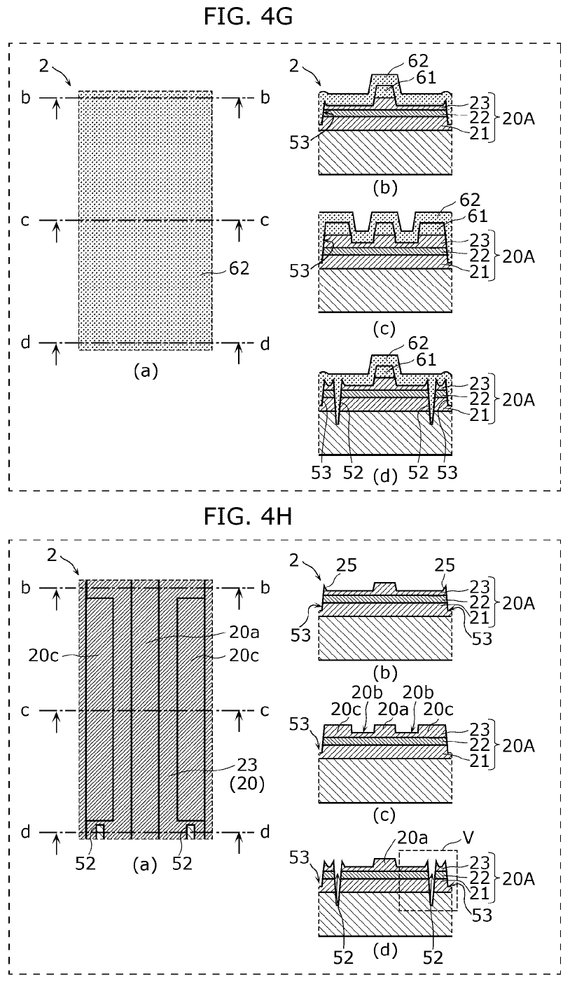

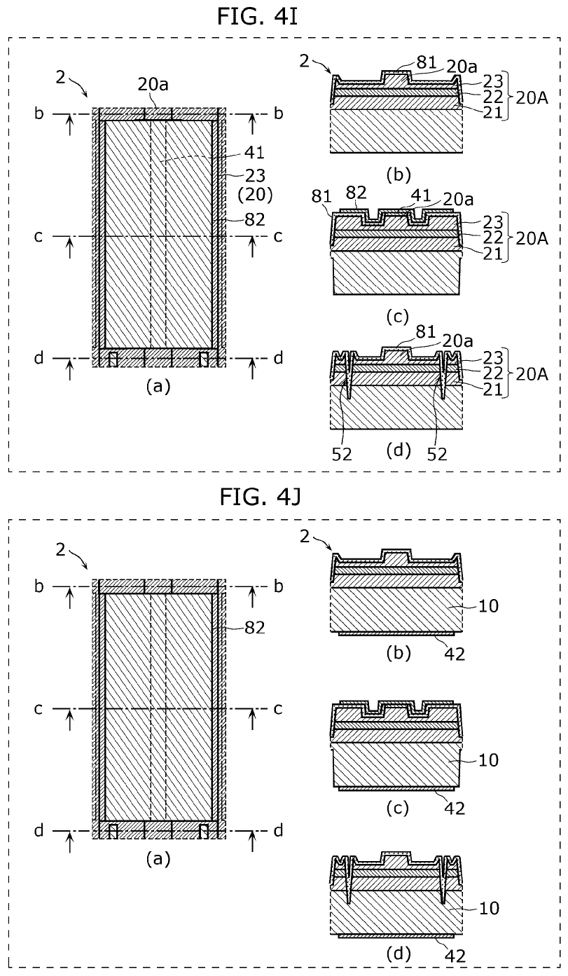

Next, a method for manufacturing semiconductor laser element 1 according to the embodiment is described with reference to FIG. 4A to FIG. 4J. FIG. 4A to FIG. 4J are each a diagram for illustrating a corresponding one of processes in the method for manufacturing semiconductor laser element 1 according to the embodiment. In FIG. 4A to FIG. 4J, (a) is a top view of semiconductor laser element 1, (b) is a cross-sectional view taken along line b-b in (a), (c) is a cross-sectional view taken along line c-c in (a), and (d) is a cross-sectional view taken along line d-d in (a). It should be noted that in (a) of FIG. 4A to FIG. 4J, hatching is used for convenience to clarify a correspondence relationship among components seen on the top face. However, insulating film 81 is omitted. In addition, FIG. 4A to FIG. 4J show only a portion of semiconductor stacked structure 20A that corresponds to one semiconductor laser element 1 and is provided on substrate 10 that is a wafer.

First, as shown in FIG. 4A, a plurality of semiconductor layers are stacked on one face of substrate 10, which is the wafer, to prepare semiconductor stacked substrate 2 including semiconductor stacked structure 20A. Specifically, first semiconductor layer 21, active layer 22, and second semiconductor layer 23 are epitaxially grown in sequence by MOCVD to form semiconductor stacked structure 20A. Next, insulating film 61 (a first insulating film) is formed on semiconductor stacked structure 20A. In the present embodiment, an SiO₂ film is formed as insulating film 61. As an example, insulating film 61 has a thickness of 300 nm. It should be noted that insulating film 61 need not be formed.

Then, as shown in FIG. 4B, first resist 71 in a predetermined shape that includes first opening portions 71a and second opening portions 71b is formed above semiconductor stacked structure 20A. First opening portions 71a are formed at positions at which second recesses 52 to be described later are formed. In addition, second opening portions 71b are formed at positions at which third recesses 53 to be described later are formed. It should be noted that since insulating film 61 is formed on semiconductor stacked structure 20A in the present embodiment, first resist 71 including first opening portions 71a and second opening portions 71b is formed on insulating film 61.

After that, as shown in FIG. 4C, semiconductor stacked structure 20A is etched (a first etching process). Specifically, semiconductor stacked structure 20A is etched using, as a mask, first resist 71 including first opening portions 71a and second opening portions 71b. Accordingly, it is possible to form recessed portions 52a in portions that correspond to first opening portions 71a in semiconductor stacked structure 20A, and at the same time it is possible to form third recesses 53 in portions that correspond to second opening portions 71b in semiconductor stacked structure 20A. It should be noted that it is possible to use, as a method for etching semiconductor stacked structure 20A, dry etching such as reactive ion etching.

Since recessed portions 52a and third recesses 53 are formed in the same etching process, recessed portions 52a and third recesses 53 have the same depth. In the present embodiment, semiconductor stacked structure 20A is etched to cause both the bottoms of recessed portions 52a and the bottoms of third recesses 53 to reach some point in first semiconductor layer 21. In other words, recessed portions 52a and third recesses 53 are formed to penetrate through second semiconductor layer 23 and active layer 22 into the inside of first semiconductor layer 21. It should be noted that since insulating film 61 is formed on semiconductor stacked structure 20A in the present embodiment, insulating film 61 is also etched. To put it another way, recessed portions 52a and third recesses 53 also penetrate through insulating film 61.

Next, as shown in FIG. 4D, first resist 71 used as the mask is removed. As a result, insulating film 61 is exposed.

Then, as shown in FIG. 4E, second resist 72 in a predetermined shape that includes opening portions 72a is formed above semiconductor stacked structure 20A. Opening portions 72a are formed at positions at which recessed portions 24 are formed in semiconductor stacked structure 20A. Additionally, opening portions 72a of second resist 72 are also formed at positions corresponding to second recesses 52. In other words, opening portions 72a are formed to overlap recessed portions 52a formed in semiconductor stacked structure 20A, and recessed portions 52a are not covered with second resist 72. In contrast, third recesses 53 formed in semiconductor stacked structure 20A are covered with second resist 72. To put it another way, second resist 72 is embedded in third recesses 53. It should be noted that since insulating film 61 is formed on semiconductor stacked structure 20A in the present embodiment, second resist 72 including opening portions 72a is formed on insulating film 61.

After that, as shown in FIG. 4F, semiconductor stacked structure 20A in which recessed portions 52a are formed is etched (a second etching process). Specifically, semiconductor stacked structure 20A is etched using, as a mask, second resist 72 including opening portions 72a. Accordingly, recessed portions 24 are formed in portions corresponding to opening portions 72a in semiconductor stacked structure 20A, and ridge portion 20a and wing portions 20c are formed in semiconductor stacked structure 20A. It should be noted that it is possible to use, as a method for etching semiconductor stacked structure 20A, dry etching such as reactive ion etching.

At this time, semiconductor stacked structure 20A is etched to cause the bottoms of recessed portions 24 to reach some point in second semiconductor layer 23. In other words, ridge portion 20a and wing portions 20c are formed in second semiconductor layer 23. It should be noted that since insulating film 61 is formed on semiconductor stacked structure 20A in the present embodiment, insulating film 61 is also etched. As a result, insulating film 61 remains only on ridge portion 20a.

Moreover, since recessed portions 52a formed in semiconductor stacked structure 20A by the first etching process are not covered with second resist 72, recessed portions 52a are further etched in this etching process. Accordingly, the bottoms of recessed portions 52a are further deepened to form second recesses 52. Specifically, recessed portions 52a formed up to first semiconductor layer 21 are further etched to reach the inside of substrate 10.

As stated above, second recesses 52 are formed using the first etching process for forming third recesses 53 and the second etching process for forming ridge portion 20a. Accordingly, it is possible to form second recesses 52 without adding a process only for forming second recesses 52. In other words, the manufacturing method in the present embodiment eliminates the need to use a mask only for forming second recesses 52.

It should be noted that, although not shown in the figure, second resist 72 used as the mask is subsequently removed. As a result, insulating film 61 on ridge portion 20a is exposed, and at the same time second semiconductor layer 23 in which recessed portions 24 are formed is exposed.

Furthermore, in the second etching process, as shown in (d) of FIG. 4F, projections 25 are formed on end edges of the top face of semiconductor stacked structure 20A (the top face of second semiconductor layer 23 in the present embodiment) in second recesses 52 and third recesses 53, in wingless portions 20d of semiconductor stacked structure 20A. It is considered that such projections 25 are formed for the following reason.

At the time of dry etching of insulating film 61 that is the first stage when ridge portion 20a is formed, flying substances at the time of dry etching are deposited to form deposits on upper portions of lateral walls of second recesses 52 and third recesses 53 of semiconductor stacked structure 20A in wingless portions 20d. Since these deposits have an etching rate lower than an etching rate of insulating film 61 (an SiO₂ film in the present embodiment), the deposits slightly remain on the upper portions of the lateral walls of second recesses 52 and third recesses 53 after etching.

Subsequently, at the time of dry etching of semiconductor stacked structure 20A (a nitride semiconductor) and substrate 10 (GaN) that is the next stage when ridge portion 20a is formed, projections 25 are formed using, as masks, the deposits remaining on the upper portions of the lateral walls of second recesses 52 and third recesses 53. It should be noted since the deposits remaining on the upper portions of the lateral walls of second recesses 52 and third recesses 53 at the first stage are etched by the dry etching of semiconductor stacked structure 20A and substrate 10, the deposits are removed during the dry etching that is the next stage.

Next, as shown in FIG. 4G, insulating film 62 (a second insulating film) is formed to cover insulating film 61 on ridge portion 20a. Specifically, insulating film 62 is formed to cover the entire top face of semiconductor stacked structure 20A. In the present embodiment, an Si0₂ film is formed as insulating film 62. As an example, insulating film 62 has a thickness of 200 nm.

Subsequently, annealing is performed to activate dopants in a p-type semiconductor layer. At this time, in the present embodiment, since not only insulating film 62 but also insulating film 61 are formed on ridge portion 20a, ridge portion 20a is protected by the two insulating films. This makes it possible to prevent ridge portion 20a from being damaged by heat in the annealing.

Then, as shown in FIG. 4H, both insulating films 61 and 62 are removed. This exposes the entire surface of semiconductor stacked structure 20A in which ridge portion 20a and wing portions 20c are formed. As a result, second recesses 52 and third recesses 53 formed in semiconductor stacked structure 20A are also exposed.

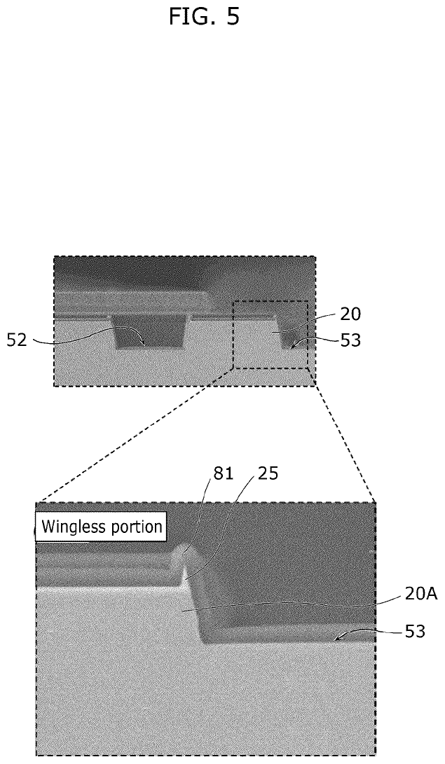

At this time, when semiconductor laser element 1 actually manufactured is checked with regard to a portion corresponding to region V enclosed by the dashed line in (d) of FIG. 4H, it is possible to verify that projection 25 is formed on an end edge of the top face of semiconductor stacked structure 20A in second recess 52 and third recess 53 as shown in FIG. 5. In addition, it is possible to verify that projection 25 is covered with insulating film 81. FIG. 5 is a cross-sectional SEM image of the portion corresponding to region V enclosed by the dashed line in (d) of FIG. 4H. It should be noted that although second recesses 52 are deeper than third recesses 53 in FIG. 4H, FIG. 5 shows second recess 52 and third recess 53 when semiconductor laser element 1 is manufactured with second recesses 52 and third recesses 53 being identical in depth.

After that, as shown in FIG. 41, p-side electrode 41 is formed on ridge portion 20a. Specifically, insulating film 81 having an opening portion is formed on the top face of ridge portion 20a, and p-side electrode 41 is formed to cover the top face of ridge portion 20a. It is possible to form p-side electrode 41 in a predetermined shape using, for example, an evaporation method and a lift-off method. Subsequently, pad electrode 82 is further formed across p-side electrode 41 and insulating film 81.

Next, as shown in FIG. 4J, n-side electrode 42 is formed on the back face of substrate 10. It is possible to form n-side electrode 42 in a predetermined shape using, for example, the evaporation method and the lift-off method.

Subsequently, although not shown in the figure, a plurality of bar-shaped substrates each including a plurality of optical waveguides are prepared by splitting semiconductor stacked substrate 2 (a primary splitting process). In the present embodiment, a plurality of bar-shaped substrates are prepared by cleaving and splitting semiconductor stacked substrate 2.

It should be noted that first recesses 51 are formed in a back face of semiconductor stacked substrate 2 or a bar-shaped substrate in advance. First recesses 51 are guide recesses for splitting the bar-shaped substrate into a plurality of semiconductor laser elements 1. Accordingly, first recess 51 is formed for each border between two adjacent semiconductor laser elements 1. In other words, first recess 51 is formed in parallel to a longitudinal direction of ridge portion 20a. In addition, first recesses 51 are located in positions recessed from both end faces when semiconductor stacked substrate 2 is split into a plurality of bar-shaped substrates. To put it another way, first recesses 51 are formed not to reach both end faces of the plurality of bar-shaped substrates. It is possible to form such first recesses 51 by irradiating the back face of substrate 10 with laser light. Specifically, first recesses 51 are laser scribe recesses formed by a laser scribe method.

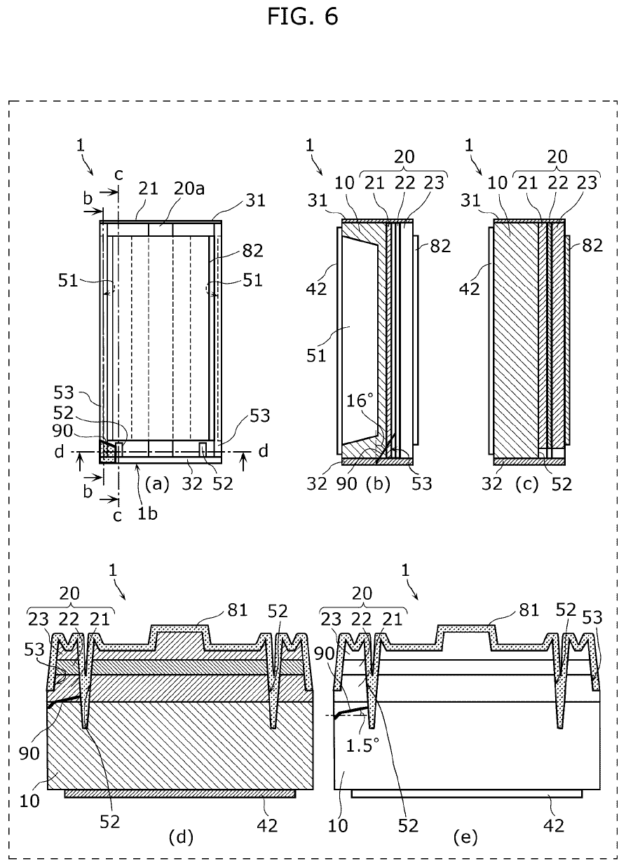

After the plurality of bar-shaped substrates are prepared by splitting semiconductor stacked substrate 2, first coating film 31 and second coating film 32 are formed on the end faces of the plurality of bar-shaped substrates. Subsequently, the plurality of semiconductor laser elements 1 each including one optical waveguide (ridge portion 20a) are prepared by splitting each of the plurality of bar-shaped substrates along first recesses 51 (a secondary splitting process). Specifically, each of the plurality of bar-shaped substrates is split in the same manner as the method shown in FIG. 8. This makes it possible to obtain semiconductor laser element 1 shown in FIG. 1 to FIG. 3. The plurality of semiconductor laser elements 1 include a semiconductor laser element that has cracked as shown in FIG. 6.

It should be noted that in FIG. 6, (a) is a top view, (b) is a cross-sectional view taken along line b-b in (a), (c) is a cross-sectional view taken along line c-c in (a), (d) is a cross-sectional view taken along line d-d in (a), and (e) is a side view when semiconductor laser element 1 is viewed from a rear side with omission of second coating film 32. It should be noted that thick lines in FIG. 6 indicate crack 90 that has occurred in semiconductor laser element 1. Since a face of crack 90 has a slope, a depth position of crack 90 in a lateral face of semiconductor stacked structure 20 is deeper than a depth position of crack 90 in the cross section along line d-d. Additionally, the dot-hatched region in (a) of FIG. 6 indicates a region in which crack 90 has occurred.

As shown in FIG. 6, in semiconductor laser element 1 thus manufactured, second recesses 52 are formed in semiconductor stacked structure 20. Second recesses 52 are formed from an end face of semiconductor stacked structure 20 in the resonator length direction.

Even if crack 90 that extends obliquely upward from the vicinity of an interface between substrate 10 and semiconductor stacked structure 20 toward a portion below ridge portion 20a occurs in the process of splitting each of the plurality of bar-shaped substrates into pieces (the secondary splitting process) as shown in FIG. 6, the above configuration enables second recess 52 to prevent crack 90 from advancing. Accordingly, since crack 90 does not extend to the portion below ridge portion 20a, it is possible to prevent the reliability of semiconductor laser element 1 from being reduced due to crack 90.

Moreover, in semiconductor laser element 1 in the present embodiment, third recesses 53 are formed in semiconductor stacked structure 20. Third recesses 53 extend in the resonator length direction of semiconductor laser element 1 as indentations in the lateral faces of semiconductor stacked structure 20.

This configuration makes it possible to improve the straightness of splitting at the time of splitting into pieces in the process of splitting into pieces.

Furthermore, in semiconductor laser element 1 in the present embodiment, second recesses 52 are deeper than a portion of the surface of semiconductor stacked structure 20 located closest to the substrate 10 side. Specifically, as shown in (d) and (e) of FIG. 6, second recesses 52 are deeper than third recesses 53.

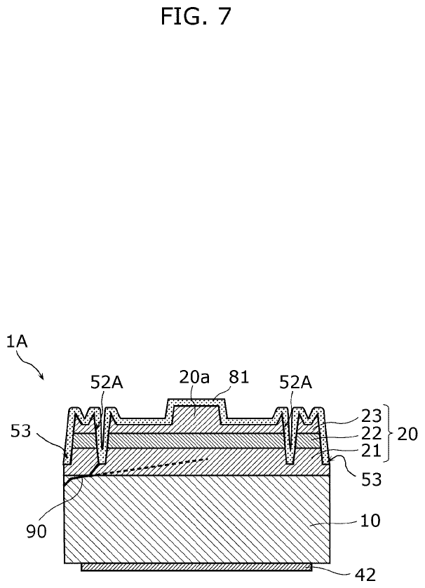

It should be noted that in semiconductor laser element 1A shown in FIG. 7, second recesses 52A and third recesses 53 are identical in depth, and the occurrence position of crack 90 is deeper than second recesses 52A and third recesses 53. In this case, although an average advancing direction of crack 90 and second recess 52A do not intersect each other as indicated by the dashed line, a sudden decrease in distance to the surface in the middle etc. changes an advancing angle of crack 90 as indicated by the solid line, and accordingly, there is a case in which it is possible to prevent crack 90 from advancing to ridge portion 20a. In view of this, by causing second recess 52 to be as deep as or deeper than third recesses 53, second recess 52 makes it possible to effectively prevent crack 90 from advancing.

It should be noted that since many cracks 90 occur from a portion lower than the portion of the surface of semiconductor stacked structure 20 (e.g., the top face of third recess 53) closest to the substrate 10 side by approximately 2 μm, the depth of second recess 52 may be caused to be at least 2 μm from the portion of the surface of semiconductor stacked structure 20 closest to the substrate 10 side.

Moreover, as stated above, in a cross section (see (d) of FIG. 6) orthogonal to the resonator length direction of semiconductor laser element 1, many cracks 90 that have occurred extends obliquely upward from the lateral face of semiconductor stacked structure 20 at an angle of 1.5° relative to a principal surface of substrate 10. In this case, depth Z of second recess 52 is expressed by Z=(A+B)−(C+D)×tanθ1, where, in wingless portion 20d, A denotes the depth of third recess 53 from the top face of semiconductor stacked structure, B denotes a length from the bottom of third recess 53 to a position of the occurrence origin of crack 90 in a depth direction, C denotes the width of third recess 53 in the top face of semiconductor stacked structure, D denotes a distance from a wall surface of third recess 53 to an outer inner face of second recess 52, and θ1 denotes an angle of crack 90 relative to the principal surface of substrate 10 in the cross section orthogonal to the resonator length direction of semiconductor laser element 1.

Here, since B=2 μm and θ1=1.5° as stated above, assuming A=1 μm, C=4 μm, and D=8 μm, Z=(1+2)−(4+8))×tan(1.5°)≈2.69 μm. In other words, by causing depth Z of second recess 52 to be at least 2.69 μm, it is possible to prevent crack 90 that occurs at the time of splitting into pieces from reaching the portion below ridge portion 20a. In addition, since a portion of the bottom of third recess 53 may chip at the time of splitting into pieces, an angle of crack 90 in the vicinity of the occurrence origin may become greater than 1.5°. As an example, the depth of second recess 52 is 1 μm or 3 μm, a distance between third recess 53 and second recess 52 is at most 9 μm (4 μm, 7 μm, 8 μm, 9 μm), and the width of third recess 53 is 4 μm.

Moreover, as stated above, in a cross section (see (b) of FIG. 6) parallel to a lateral face of semiconductor laser element 1, many cracks 90 that have occurred extends obliquely upward from the end face of semiconductor stacked structure 20 at an angle of 16° relative to the principal surface of substrate 10. In this case, length Y of second recess 52 in the resonator length direction from the rear end face of semiconductor stacked structure 20 is expressed by Y=(A+B)/tan θ2 using above A and B, where θ2 denotes an angle of crack 90 relative to the principal surface of substrate 10 in the cross section parallel to the lateral face of semiconductor laser element 1 in wingless portion 20d.

Here, since B=2 μm and θ2=16° as stated above, assuming A=1 μm, Y=(1+2)/tan (16°)≈10.5 μm. In other words, by causing length Y of second recess 52 in the resonator length direction to be at least 10.5 μm (at least 10 μm), it is possible to prevent crack 90 that occurs at the time of splitting into pieces from reaching the portion below ridge portion 20a.

It should be noted that length Y of second recess 52 in the resonator length direction may be at most 25 times a distance between third recess 53 and second recess 52. This makes it possible to prevent a defect such as chipping from occurring between third recess 53 and second recess 52.

Furthermore, as shown in (d) and (e) of FIG. 6, in semiconductor laser element 1 in the present embodiment, third recesses 53 are deeper than active layer 22 that is the PN junction portion in semiconductor stacked structure 20.

This configuration makes it possible to isolate semiconductor laser element 1 easily using third recesses 53. In addition, although when third recesses 53 are shallower than the PN junction portion, there is a possibility of a leak occurring in the PN junction portion due to exposure of the PN junction portion at the time of splitting into pieces, it is possible to prevent a leak from occurring in the PN junction portion at the time of splitting into pieces, by causing third recesses 53 to be deeper than the PN junction portion.

It should be noted that decreasing the depth of third recesses 53 causes a position of the occurrence origin of crack 90 in a corner portion of semiconductor stacked structure 20 to be shallow. In other words, the length of crack 90 extending obliquely upward from the lateral face of semiconductor stacked structure 20 is reduced. As an example, third recess 53 has a depth of 1 μm to 3 μm. It is possible to shorten a distance of crack 90 to the surface by decreasing the depth of the origin of crack 90.

Moreover, in semiconductor laser element 1 in the present embodiment, a lateral face of second recess 52 is sloped. Additionally, a lateral face of third recess 53 is also sloped.

This configuration makes it possible to cause an angle defined by the top face of semiconductor stacked structure 20 and the lateral face of second recess 52 to be an obtuse angle. In addition, it is possible to cause an angle defined by the top face of semiconductor stacked structure 20 and the lateral face of third recess 53 to be an obtuse angle. Accordingly, it is possible to prevent chipping from occurring in peripheral portions of second recess 52 and third recess 53 in semiconductor stacked structure 20 at the time of the primary splitting process of splitting semiconductor stacked substrate 2 into a plurality of bar-shaped substrates.

Furthermore, in semiconductor laser element 1 in the present embodiment, a distance between second recess 52 and ridge portion 20a is at least 4 μm in a top view. This configuration allows second recess 52 to efficiently prevent crack 90 that extends obliquely upward from the lateral face of semiconductor laser element 1 (semiconductor stacked structure 20) from advancing, and at the same time makes it possible to effectively perform lateral current limitation. It should be noted that when second recess 52 is farther from the lateral face of semiconductor laser element 1 (semiconductor stacked structure 20), second recess 52 makes it possible to more efficiently prevent crack 90 that advances obliquely upward. In other words, second recess 52 may be closer to ridge portion 20a than to the lateral face of semiconductor laser element 1.

Moreover, in semiconductor laser element 1 in the present embodiment, the length of second recess 52 in the resonator length direction is at least half a distance between first recess 51 and an end face of semiconductor stacked structure 20. As an example, the length of second recess 52 in the resonator length direction is 14 μm, and the distance between first recess 51 and the end face of semiconductor stacked structure 20 is 13 μm.

This configuration makes it possible to effectively prevent crack 90 itself from occurring.

Furthermore, in semiconductor laser element 1 according to the present embodiment, projection 25 is provided on a surface of an end edge of semiconductor stacked structure 20 in a direction orthogonal to the resonator length direction of semiconductor stacked structure 20, in wingless portion 20d. Specifically, projection 25 is provided on the end edge that is a border between the surface of semiconductor stacked structure 20 and the lateral face of second recess 52.

Additionally, projection 25 is also provided on the end edge that is a border between the surface of semiconductor stacked structure 20 and the lateral face of third recess 53.

In the splitting process of splitting a wafer (the primary splitting process, the secondary splitting process), when a protection component comprising SiO₂ etc. is disposed on the wafer, the height of the protection component is greater than or equal to the height of ridge portion 20a. For this reason, the above configuration makes it possible to prevent stress at the time of splitting from being applied to ridge portion 20a. Accordingly, it is possible to prevent a chip (e.g., an end face step) from occurring in ridge portion 20a due to the stress at the time of splitting.

In addition, since projection 25 is provided to semiconductor stacked structure 20, it is possible to increase a surface area of semiconductor stacked structure 20. As a result, when semiconductor laser element 1 is mounted on a submount using solder, a contact area between the solder and semiconductor laser element 1 increases. For this reason, it is possible to improve joint properties and adhesiveness.

### Variations

Although the semiconductor laser element and the method for manufacturing the same according to the present disclosure have been described above based on the embodiment, the present disclosure is not limited to the aforementioned embodiment.

For example, although a waveguide in semiconductor laser element 1 is ridge portion 20a in the aforementioned embodiment, the present disclosure is not limited to this example. For example, the waveguide in semiconductor laser element 1 may have an electrode stripe structure including only split electrodes or a current limiting structure including a current block layer, instead of a ridge stripe structure including ridge portion 20a.

Moreover, although the case in which semiconductor laser element 1 in the aforementioned embodiment comprises the nitride-based semiconductor material has been described as an example, the present disclosure is not limited to this example. For example, it is possible to apply the present disclosure to a case in which a semiconductor material other than a nitride-based semiconductor material is used.

Forms obtained by various modifications to the aforementioned embodiment that can be conceived by a person skilled in the art as well as forms achieved by combining the constituent elements and functions in the embodiment in any manner as long as they do not depart from the essence of the present disclosure are included in the present disclosure.

Although only one exemplary embodiment of the present disclosure has been described in detail above, those skilled in the art will readily appreciate that many modifications are possible in the exemplary embodiment without materially departing from the novel teachings and advantages of the present disclosure. Accordingly, all such modifications are intended to be included within the scope of the present disclosure.

### INDUSTRIAL APPLICABILITY

The semiconductor laser element according to the present disclosure is useful as a light source element for various products such as projectors, optical disks, vehicle headlamps, lighting devices, or laser processing devices.

1. A semiconductor laser element including a resonator end face and a pair of lateral faces that intersect the resonator end face, the semiconductor laser element comprising:
a substrate; and
a semiconductor stacked structure that is provided on one face of the substrate and in which a plurality of semiconductor layers are stacked,
wherein the semiconductor stacked structure includes an optical waveguide that extends in a resonator length direction of the semiconductor laser element,
a pair of first recesses are provided in an other face of the substrate as indentations in the pair of lateral faces, the pair of first recesses extending in the resonator length direction,
both end portions of each of the pair of first recesses in the resonator length direction are located in positions recessed from end faces of the semiconductor stacked structure,
a plurality of second recesses are provided in the semiconductor stacked structure, the plurality of second recesses extending from one of the end faces of the semiconductor stacked structure in the resonator length direction, and
in a top view, the plurality of second recesses are provided on both sides of the optical waveguide, and are each provided between a corresponding one of the pair of first recesses and the optical waveguide.

2. The semiconductor laser element according to claim 1,
wherein a third recess is provided in the semiconductor stacked structure as an indentation in a lateral face of the semiconductor stacked structure, the third recess extending in the resonator length direction.

3. The semiconductor laser element according to claim 2,
wherein the plurality of second recesses are deeper than or as deep as a portion of a surface of the semiconductor stacked structure that is located closest to a substrate side.

4. The semiconductor laser element according to claim 2,
wherein the plurality of second recesses are deeper than or as deep as the third recess.

5. The semiconductor laser element according to claim 2,
wherein a length of each of the plurality of second recesses in the resonator length direction is at least 10 μm from the one of the end faces of the semiconductor stacked structure and is at most 25 times a distance between the third recess and the second recess.

6. The semiconductor laser element according to claim 2,
wherein the semiconductor stacked structure includes a PN junction portion, and
the third recess is deeper than the PN junction portion.

7. The semiconductor laser element according to claim 2,
wherein a lateral face of the third recess is sloped.

8. The semiconductor laser element according to claim 1,
wherein in the top view, a distance between each of the plurality of second recesses and the optical waveguide is at least 4 μm.

9. The semiconductor laser element according to claim 1,
wherein the plurality of second recesses are provided from one of the end faces of the semiconductor stacked structure that is opposite to a face of the semiconductor stacked structure through which laser light is emitted.

10. The semiconductor laser element according to claim 1,
wherein a lateral face of each of the plurality of second recesses is sloped.

11. The semiconductor laser element according to claim 1,
wherein a length of each of the plurality of second recesses in the resonator length direction is at least half a distance between the corresponding one of the pair of first recesses and the one of the end faces of the semiconductor stacked structure.

12. The semiconductor laser element according to claim 1,
wherein each of the plurality of semiconductor layers comprises a nitride-based semiconductor material.

13. The semiconductor laser element according to claim 1,
wherein a width of each of the plurality of second recesses in a direction orthogonal to the resonator length direction is at most 10 μm.

14. A semiconductor laser element comprising:
a substrate; and
a semiconductor stacked structure that is provided on one face of the substrate and in which a plurality of semiconductor layers are stacked,
wherein the semiconductor stacked structure includes a ridge portion that extends in a resonator length direction of the semiconductor laser element, and
a projection is provided on a surface of an end edge of the semiconductor stacked structure in a direction orthogonal to the resonator length direction.

15. The semiconductor laser element according to claim 14,
wherein the semiconductor stacked structure includes a wing portion on a side of the ridge portion, the wing portion having a same height as the ridge portion,
a wingless portion is provided in a vicinity of an end face of the semiconductor stacked structure, the wingless portion being a portion in which the wing portion is not provided, and
the projection is provided on the surface of the end edge of the semiconductor stacked structure in the direction orthogonal to the resonator length direction, in the wingless portion.

16. The semiconductor laser element according to claim 14,
wherein a recess is provided in the semiconductor stacked structure, the recess extending from an end face of the semiconductor stacked structure in the resonator length direction, and
the end edge is a border between a surface of the semiconductor stacked structure and a lateral face of the recess.

17. The semiconductor laser element according to claim 14,
wherein a recess is provided in the semiconductor stacked structure as an indentation in a lateral face of the semiconductor stacked structure, the recess extending in the resonator length direction, and
the end edge is a border between a surface of the semiconductor stacked structure and a lateral face of the recess.

18. The semiconductor laser element according to claim 14,
wherein each of the plurality of semiconductor layers comprises a nitride-based semiconductor material.

19. A method for manufacturing a semiconductor laser element, the method comprising:
a process of stacking a plurality of semiconductor layers on one face of a substrate to prepare a semiconductor stacked substrate including a semiconductor stacked structure;
a first etching process of etching the semiconductor stacked structure;
a second etching process of etching the semiconductor stacked structure after the first etching process;
a first splitting process of splitting the semiconductor stacked substrate into a plurality of bar-shaped substrates each of which includes a plurality of optical waveguides;
a process of forming a plurality of first recesses on a back face of the semiconductor stacked substrate or a back face of each of the plurality of bar-shaped substrates; and
a second splitting process of splitting each of the plurality of bar-shaped substrates along the plurality of first recesses to prepare a plurality of semiconductor laser elements each of which includes one optical waveguide,
wherein in the first etching process, a recessed portion is formed in the semiconductor stacked structure,
in the second etching process, the recessed portion is further etched to form a plurality of second recesses, and a ridge portion is formed as the one optical waveguide in the semiconductor stacked structure, and
in a top view, the plurality of second recesses are formed to extend, on both sides of the one optical waveguide, from an end face of the semiconductor stacked structure in a resonator length direction of the plurality of semiconductor laser elements, and are each formed between a corresponding one of the plurality of first recesses and the one optical waveguide.

20. The method for manufacturing the semiconductor laser element according to claim 19,
wherein each of the plurality of semiconductor layers comprises a nitride-based semiconductor material.
